(19) United States
(12) Patent Application Publication
(10) Pub. No.: US 2026/0165204 A1
(43) Pub. Date: Jun. 11, 2026

(54) SEMICONDUCTOR PACKAGE

(71) Applicant: Samsung Electronics Co., Ltd., Suwon-si (KR)

(72) Inventors: IN-JAE LEE, Suwon-si (KR); DONGOK KWAK, Suwon-si (KR); TAE-YOUNG LEE, Suwon-si (KR)

(21) Appl. No.: 19/231,695

(22) Filed: Jun. 9, 2025

(30) Foreign Application Priority Data
Dec. 11, 2024 (KR) 10-2024-0183626

(51) Int. Cl. H01L 23/00; H01L 25/065; H01L 25/16

(52) U.S. Cl. CPC H10W 90/00; H10W 72/01323; H10W 72/07353; H10W 72/334; H10W 72/621; H10W 72/865; H10W 72/921; H10W 72/932; H10W 90/24; H10W 90/738; H10W 90/754; H10W 90/762; H10W 90/764

(57) ABSTRACT

A semiconductor package may include a substrate, a semiconductor chip disposed on the substrate, electrically connected to the substrate, and having a connection pad at a surface of the semiconductor chip, a passive component disposed on the semiconductor chip, and a first conductive pattern extending from the connection pad to an outer side of the connection pad along the surface of the semiconductor chip and electrically connecting the semiconductor chip and the passive component, at least a portion of which is disposed between the semiconductor chip and the passive component.

### CROSS-REFERENCE TO RELATED APPLICATION

This application claims priority to and the benefit of Korean Patent Application No. 10-2024-0183626 filed with the Korean Intellectual Property Office on Dec. 11, 2024, the entire contents of which are incorporated herein by reference.

### BACKGROUND OF THE INVENTION

### (a) Field of the Invention

The present disclosure relates to a semiconductor package.

### (b) Description of the Related Art

In the semiconductor packaging industry, various technologies are being studied to improve signal quality to simultaneously meet high performance and high reliability. Among these technologies, a structure is known in which semiconductor chips and multilayer ceramic capacitors (MLCCs) are disposed side by side on a substrate and the semiconductor chips and the MLCCs are connected through the substrate. The MLCCs connected to the semiconductor chips can improve the performance and reliability of semiconductor packages through various roles such as stable power supply, high-frequency noise filtering, and EMI suppression.

### SUMMARY OF THE INVENTION

In one aspect, the present disclosure provides a semiconductor package having excellent electrical characteristics by shortening an electrical connection path between a semiconductor chip and a passive component.

In another aspect, the present disclosure provides a miniaturized semiconductor package.

A semiconductor package may include a substrate, a semiconductor chip disposed on the substrate, electrically connected to the substrate, and having a connection pad at a surface of the semiconductor chip, a passive component disposed on the semiconductor chip, and a first conductive pattern extending from the connection pad to an outer side of the connection pad, along the surface of the semiconductor chip, and electrically connecting the semiconductor chip and the passive component; at least a portion of which is disposed between the semiconductor chip and the passive component.

A semiconductor package may include a substrate, a semiconductor chip disposed on the substrate, electrically connected to the substrate, and having a plurality of connection pads including a first connection pad and second connection pad at a surface of the semiconductor chip, a passive component disposed on the semiconductor chip, and having a first electrode and a second electrode, a first conductive pattern extending from the first connection pad to an outer side of the first connection pad along the surface of the semiconductor chip, wherein the first conductive pattern includes a first pad region, at least a portion of which is disposed between the semiconductor chip and the first electrode, and a first connection region connecting the first pad region and the first connection pad, and electrically connecting the first connection pad and the first electrode, and a second conductive pattern extending from the second connection pad to an outer side of the second connection pad, along the surface of the semiconductor chip, in which the second conductive pattern includes a second pad region, at least a portion of which is disposed between the semiconductor chip and the second electrode and a second connection region connecting the second pad region and the second connection pad, and electrically connecting the second connection pad and the second electrode.

A semiconductor package may include a substrate, a plurality of semiconductor chips disposed on the substrate, electrically connected to the substrate, and having a plurality of connection pads at a surface of each corresponding semiconductor chip of the plurality of semiconductor chips, in which each semiconductor chip of the plurality of semiconductor chips is stacked to be offset such that each connection pad of the plurality of connection pads at the surface of the corresponding semiconductor chip is exposed, a passive component disposed on a first semiconductor chip of the plurality of semiconductor chips, and a first conductive pattern extending from the connection of the first semiconductor chip to an outer side of the connection pad, along a surface of the first semiconductor chip, and electrically connecting the first semiconductor chip and the passive component, at least a portion of which is disposed between the first semiconductor chip and the passive component.

A manufacturing method of a semiconductor package may include disposing a semiconductor chip having a connection pad, on a substrate, forming a conductive pattern extending from the connection pad of the semiconductor chip to an outer side of the connection pad, along a surface of the semiconductor chip and disposing a passive component on the conductive pattern.

According to examples, manufacturing methods are provided that include disposing a semiconductor chip having a connection pad on a substrate, which the semiconductor chip is electrically connected to the substrate, disposing a passive component on the conductive pattern, and forming a conductive pattern extending from the connection pad of the semiconductor chip, along a surface of the semiconductor chip and electrically connecting the semiconductor chip and the passive component, at least a portion of which is between the semiconductor chip and the passive component.

### BRIEF DESCRIPTION OF THE DRAWINGS

FIG. 1 is a perspective view of a semiconductor package according to an embodiment.

FIG. 2 is a partial cross-sectional view of the semiconductor package shown in FIG. 1.

FIG. 3 is a partial plan view of the semiconductor package shown in FIG. 1.

FIG. 4 is a perspective view of a semiconductor package according to another embodiment.

FIG. 5 is a partial plan view of the semiconductor package shown in FIG. 4.

FIG. 6 is a perspective view of a semiconductor package according to still another embodiment.

FIG. 7 is a perspective view of a semiconductor package according to still another embodiment.

FIG. 8 to FIG. 11 are schematic manufacturing process diagrams of the semiconductor package shown in FIG. 6.

### DETAILED DESCRIPTION OF THE EMBODIMENTS

The present disclosure will be described more fully hereinafter with reference to the accompanying drawings, in which exemplary embodiments of the disclosure are shown. As those skilled in the art would realize, the described embodiments may be modified in various different ways, all without departing from the spirit or scope of the present disclosure.

The drawings and description are to be regarded as illustrative in nature and not restrictive. Like reference numerals designate like elements throughout the specification.

The term “same,” as used herein when referring to a component does not necessarily mean an exactly identical component, but is intended to encompass nearly identical components within typical variations that may occur resulting from conventional manufacturing processes. The term “substantially” may be used herein to emphasize this meaning, unless the context indicates otherwise.

Further, because sizes and thicknesses of constituent members shown in the accompanying drawings are arbitrarily given for better understanding and ease of description, the present disclosure is not limited to the illustrated sizes and thicknesses. In the drawings, the thicknesses of layers, films, regions, etc., may be exaggerated for clarity. For better understanding and ease of description, the thickness of some layers and areas is exaggerated.

Throughout this specification when an element is described as “connected” to another element, the element may be “directly connected” to the other element or “indirectly connected” to the other element through a third element. In a similar sense, this includes being “physically connected” as well as being “electrically connected”. In contrast, when an element is referred to as being “directly connected” to another element, or as “contacting” or “in contact with” another element (or using any form of the word “contact”), there are no intervening elements present at the point of contact

As used herein, items described as being “electrically connected” are configured such that an electrical signal can be passed from one item to the other. Therefore, a passive electrically conductive component (e.g., a wire, pad, internal electrical line, etc.) physically connected to a passive electrically insulative component (e.g., a prepreg layer of a printed circuit board, an electrically insulative adhesive connecting two devices, an electrically insulative underfill or mold layer, etc.) is not electrically connected to that component.

It will be understood that when an element such as a layer, film, region, or substrate is referred to as being “on” another element, it can be directly on the other element or intervening elements may also be present. In contrast, when an element is referred to as being “directly on” or “directly formed on” another element, there are no intervening elements present. Spatially relative terms, such as “below,” “lower,” “above,” “upper,” “uppermost,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, in the specification, the word “on” means positioned above or below the object portion, and does not necessarily mean positioned on the upper side of the object portion based on a gravitational direction. For example, if the device in the figures is turned over, elements described as “below” other elements would then be oriented “above” the other elements. Thus, the term “below” can encompass both an orientation of above and below. The device may be otherwise oriented (rotated 90 degrees or at other orientations) and the spatially relative descriptors used herein interpreted accordingly.

As used herein the term “cover” is intended to mean that an element is over or aside another element. The elements may be touching or not. An element that “covers” another element need not cover an entire element to be considered to “cover” the element. The terms are intended to encompass one element covering all, or any part of, an element below it.

In addition, unless explicitly described to the contrary, the words “comprise” and variations such as “comprises” or “comprising”, and “include” and variations such as “includes” and “including”, will be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

In addition, throughout the specification, sequential numbers such as first and second, etc. are used to distinguish a certain component from another component that is the same or similar to the certain component, and are not necessarily intended to refer to a specific component. Accordingly, a component referred to as a first component in a particular portion of the specification may be referred to as a second component in another portion of the specification or in the claims without departing from the teachings of the present application. In addition, in certain cases, even if a term is not described using “first,” “second,” etc., in the specification, it may still be referred to as “first”, “second”, etc. in a claim to distinguish different claimed elements from each other.

In addition, throughout the specification, a singular reference to a component includes references to a plurality of these components, unless specifically stated to the contrary.

The various pads of a device described herein may be conductive terminals connected to internal wiring of the device, and may transmit signals and/or supply voltages between an internal wiring and/or internal circuit of the device and an external source. For example, chip pads of a semiconductor chip may electrically connect to and transmit supply voltages and/or signals between an integrated circuit of the semiconductor chip and a device to which the semiconductor chip is connected. The various pads may be provided on or near an external surface of the device and may have a planar surface having dimensions greater than wiring (e.g., X-Y horizontal dimensions of a pad are both greater than the width of an internal wiring to which it is connected) to promote an electrical connection to a further terminal, such as a bump or solder ball, and/or an external wiring.

Hereinafter, a semiconductor package according to embodiments of the present disclosure will be described with reference to the drawings.

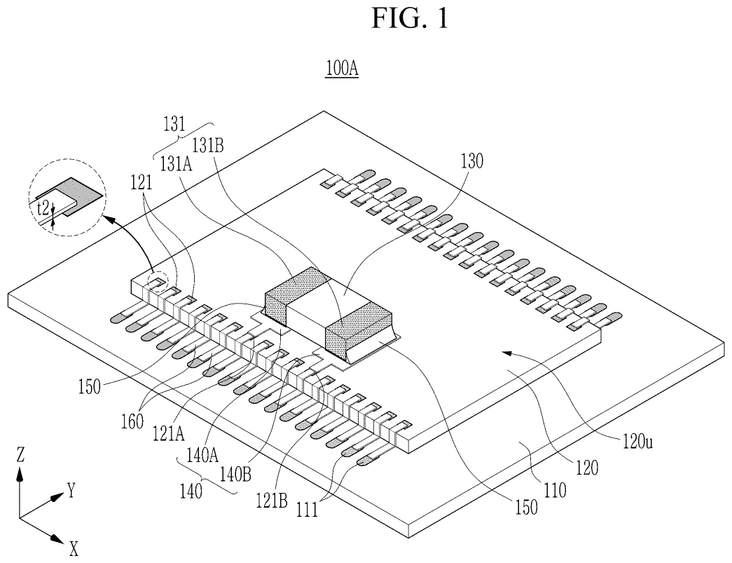

FIG. 1 is a perspective view of a semiconductor package according to an embodiment.

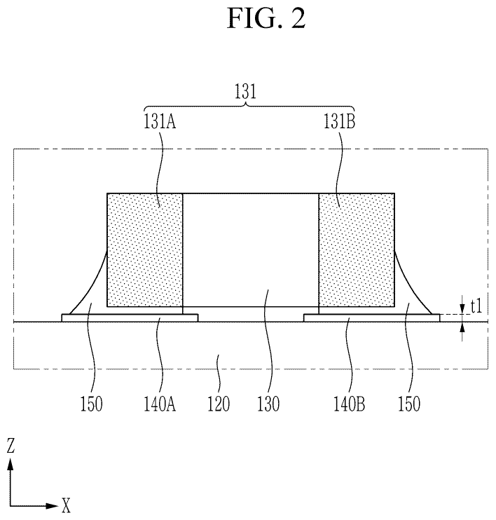

FIG. 2 is a partial cross-sectional view of the semiconductor package shown in FIG. 1.

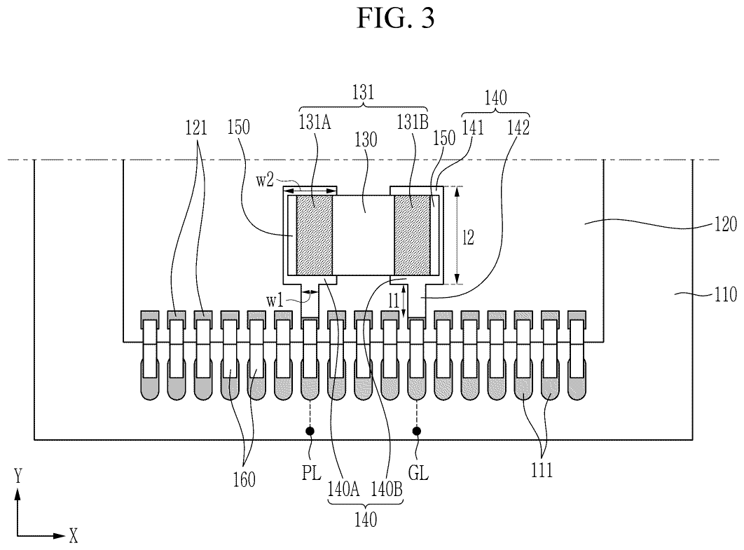

FIG. 3 is a partial plan view of the semiconductor package shown in FIG. 1.

A semiconductor package 100A according to an embodiment may include a substrate 110, a semiconductor chip 120, a passive component 130, a first conductive pattern 140, a conductive member 150 and a second conductive pattern 160.

The substrate 110 may be, for example, a printed circuit board (PCB).

The substrate 110 may have wires that perform various functions, such as signal wires for signal transmission, power wires for power supply, ground wires for providing ground.

The substrate 110 may have other components, for example, pads 111 for electrical connection to the semiconductor chip 120.

The pads 111 may be disposed on an edge region of the substrate 110. For example, the pads 111 may include pads arranged along an X-direction X on a side edge region of the substrate 110 in a Y-direction Y. Depending on embodiments, the pads 111 may further include pads arranged along the Y-direction Y in a side edge region of the substrate 110 in the X-direction X, and may be arranged along an entire edge region of the substrate 110.

As the material of the pad 111, conductive materials, for example, aluminum (Al), copper (Cu), gold (Au), platinum (Pt), silver (Ag), tin (Sn), chromium (Cr), palladium (Pd), or an alloy of two or more these, may be used. The drawings illustrate only the pad 111 disposed on an upper surface of the substrate 110, but pads for electrical connection to other components such as a main board may also exist on a lower surface of the substrate 110.

The semiconductor chip 120 may be disposed on the substrate 110 and electrically connected to the substrate 110.

The semiconductor chip 120 may have a plurality of connection pads 121, each connection pad 121 of the plurality of connection pads 121 being electrically connected to the pad 111 of the substrate 110.

The semiconductor chip 120 may be disposed in a face up shape so that a first surface 120u where the connection pad 121 is disposed may face upward. The first surface 120u where the connection pad 121 of the semiconductor chip 120 is disposed may be an active surface adjacent to an internal wire of the semiconductor chip 120, and an opposite surface (a surface facing the substrate 110) of the first surface 120u may be an inactive surface adjacent to a semiconductor substrate where the internal wire of the semiconductor chip 120 is formed.

The plurality of connection pads 121 may be disposed on an edge region of the semiconductor chip 120. For example, the plurality of connection pads 121 may include connection pads 121 arranged along the X-direction X in a side edge region of the semiconductor chip 120 in the Y-direction Y. According to example embodiments, the plurality of connection pads 121 may further include connection pads 121 arranged along the Y-direction Y in a side edge region of the semiconductor chip 120 in the X-direction X, and may be arranged along an entire edge region of the semiconductor chip 120.

The plurality of connection pads 121 may include, for example, a first connection pad 121A and a second connection pad 121B, each being electrically connected to the passive component 130. The first connection pad 121A and the second connection pad 121B may also each be electrically connected to the pad 111 of the substrate 110. For example, the first connection pad 121A and the second connection pad 121B may be electrically connected to the passive component 130 through the first conductive pattern 140, and may be electrically connected to the pad 111 of the substrate 110 through the second conductive pattern 160.

As the material of the connection pad 121, a conductive material, for example, aluminum (Al), copper (Cu), gold (Au), platinum (Pt), silver (Ag), tin (Sn), chromium (Cr), palladium (Pd), or an alloy of two or more these, may be used.

The type of the semiconductor chip 120 is not particularly limited, and may be, for example, various types of chips such as a logic chip, a memory chip, or the like. The logic chip may include at least one of an application processor (AP), a microprocessor, a central processing unit (CPU), a graphics processing unit (GPU), a neural processing unit (NPU), an application-specific integrated circuit (ASIC), or a system-on-chip (SoC). The memory chip may include at least one of high-bandwidth memory (HBM) chip, dynamic random-access memory (DRAM) chip, static random-access memory (SRAM) chip, flash memory chip, read-only memory (ROM) chip or magnetic random-access memory (MRAM) chip.

The passive component 130 may be disposed on the semiconductor chip 120, and may be electrically connected to the semiconductor chip 120. The passive component 130 may be disposed on the first surface 120u where the connection pad 121 of the semiconductor chip 120 is disposed, and may be connected to the connection pad 121 through a short electrical path through the first conductive pattern 140 extending along a surface of the first surface 120u.

The passive component 130 may not overlap with the connection pads 121A and 121B electrically connected thereto, and may be spaced apart from the connection pads 121A and 121B by a predetermined distance. Because the passive component 130 and the connection pads 121A and 121B do not overlap in examples, the arrangement space of the plurality of connection pads 121 arranged in a narrow pitch may be secured. For example, to secure the arrangement space of the plurality of connection pads 121 arranged in the X-direction X, the passive component 130 may be spaced apart from the plurality of connection pads 121 in the Y-direction Y. In addition, because the passive component 130 and the plurality of connection pads 121 do not overlap, the second conductive pattern 160 for electrical connection to the substrate 110 may be easily connected to the first connection pad 121A and the second connection pad 121B electrically connected to the passive component 130.

The passive component 130 may have a first electrode 131A and a second electrode 131B. Because the first electrode 131A and the second electrode 131B are spaced apart in the X-direction X, they may be disposed adjacent to the plurality of connection pads 121 arranged along the X-direction X. The first electrode 131A may be electrically connected to a power wire PL of the substrate 110 via the first connection pad 121A, and the second electrode 131B may be electrically connected to a ground wire GL of the substrate 110 via the second connection pad 121B.

As the material of the electrode 131, conductive materials may be used, for example, at least one conductive material selected from tin (Sn), copper (Cu), aluminum (Al), nickel (Ni), gold (Au), silver (Ag), palladium (Pd), titanium (Ti), or an alloy thereof may be used. In examples, the electrode 131 may include a plurality of layers.

The passive component 130 may include a multilayer ceramic capacitor (MLCC). However, the type of the passive component 130 is not limited thereto, and the passive component 130 may be other types of capacitors such as a tantalum capacitor, and may be other types of passive components such as an inductor and a resistor.

The first conductive pattern 140 may extend from the connection pad 121 to an outer side of the connection pad 121 along a surface, such as the first surface 120u of the semiconductor chip 120. Accordingly, one end of the conductive pattern 140 may be disposed on the connection pad 121, and the other end of the conductive pattern 140 may be disposed outside the connection pad 121 such that the other end of the conductive pattern 140 does not overlap with the connection pad 121 in a plan view. At least a portion of the first conductive pattern 140 (e.g. the other end of the first conductive pattern 140) may be disposed between the semiconductor chip 120 and the passive component 130, and may electrically connect the semiconductor chip 120 and the passive component 130.

The first conductive pattern 140 may include a pad region 141 and a connection region 142 (refer to FIG. 3). At least a portion (e.g., the electrode 131 of the passive component 130) of the passive component 130 may be disposed in the pad region 141, and accordingly, at least a portion of the pad region 141 may be disposed between the semiconductor chip 120 and the passive component 130 of the first conductive pattern 140. The connection region 142 may connect the pad region 141 and the connection pad 121.

The pad region 141 and the connection region 142 are intended to distinguish and refer to specific regions of the first conductive pattern 140, and these may be formed by the same process, for example, direct printing process, and may not have a boundary by being integrated with each other.

Because the plurality of connection pads 121 exist around the connection region 142, the connection region 142 may have a narrow line width, such as the same width as a connection pad 121 of the plurality of connection pads 121. In addition, the connection region 142 may have a short length, to provide a short electrical connection path between the connection pad 121 and the pad region 141. In examples, the pad region 141 may have a relatively wide range to provide a stable connection. For example, a width w1 of the connection region 142 in the X-direction X may be narrower than a width w2 of the pad region 141 in the X-direction X. In addition, a length l1 of the connection region 142 in the Y-direction Y may be shorter than a length l2 of the pad region 141 in the Y-direction Y.

The first conductive pattern 140 may cover at least a portion of the connection pad 121. The first conductive pattern 140 may contact the connection pad 121, or may cover the connection pad 121 in a state that other components are interposed between the first conductive pattern 140 and the connection pad 121. In an embodiment, the first conductive pattern 140 may cover at least a portion of the connection pad 121, and the second conductive pattern 160 may cover another portion of the connection pad 121. In another embodiment, the first conductive pattern 140 and the second conductive pattern 160 may be sequentially formed in a vertical direction, so that the first conductive pattern 140 may cover at least a portion of the connection pad 121, and the second conductive pattern 160 may cover at least a portion of the first conductive pattern 140 on the connection pad 121 (e.g., so that the first conductive pattern 140 is vertically between the second conductive pattern 160 and the connection pad 121). In still another embodiment, the second conductive pattern 160 and the first conductive pattern 140 may be sequentially formed in a vertical direction, so that the second conductive pattern 160 may cover at least a portion of the connection pad 121, and the first conductive pattern 140 may cover at least a portion of the second conductive pattern 160 on the connection pad 121 (e.g., so that the second conductive pattern 160 is vertically between the first conductive pattern 160 and the connection pad 121).

The first conductive pattern 140 may include a 1-1-th conductive pattern 140A connecting the first connection pad 121A of the semiconductor chip 120 and the first electrode 131A of the passive component 130 and a 1-2-th conductive pattern 140B connecting the second connection pad 121B of the semiconductor chip 120 and the second electrode 131B of the passive component 130. The 1-1-th conductive pattern 140A and the 1-2-th conductive pattern 140B may be spaced apart from each other to prevent electric short-circuiting, and for example, may be spaced apart in the X-direction X, which is a direction in which the first electrode 131A and the second electrode 131B are spaced apart.

As the forming material of the first conductive pattern 140, conductive materials may be used, and for example, it may be formed of a conductive ink that includes metal particles such as aluminum (Al), copper (Cu), gold (Au), platinum (Pt), silver (Ag), and/or nickel (Ni), binder resin, additive (e.g., dispersants, during agents, or the like), solvent, or the like. The solvent of the conductive ink may be removed through a drying process, a curing process, or the like, and may not remain in the first conductive pattern 140. As still another example, as the material of the first conductive pattern 140, a metallic material such as aluminum (Al), copper (Cu), gold (Au), platinum (Pt), silver (Ag), tin (Sn), chromium (Cr), palladium (Pd), or an alloy of two or more these may be used.

The first conductive pattern 140 may be formed, for example, on a surface of the semiconductor chip 120 through a direct printing process. For example, the first conductive pattern 140 may be formed by screen printing, Inkjet printing, aerosol jet printing, or the like.

The first conductive pattern 140 formed through a direct printing process may have a thin thickness. For example, a thickness t1 of the first conductive pattern 140 may be several hundreds of nanometers (nm), several micron (μm), or tens of microns. By forming the first conductive pattern 140 in a thin thickness, it is possible to achieve thinning of the semiconductor package 100A.

The conductive member 150 may be disposed between the first conductive pattern 140 and the passive component 130, to electrically connect the first conductive pattern 140 and the passive component 130. The conductive member 150 may be formed of a solder paste, for example, and may be formed by applying the solder paste to the electrode 131, disposing the passive component 130 on the first conductive pattern 140 and then melting and cooling the solder paste by the solder reflow process. The conductive member 150 may extend vertically and horizontally, and may include a portion that contacts a bottom surface of the electrode 131 and a portion that contacts a side surface of the electrode 131. The conductive member 150 may cover a bottom edge of the electrode 131.

The second conductive pattern 160 may extend along the surface of the semiconductor chip 120 and the surface of the substrate 110, and may electrically connect the connection pad 121 and the substrate 110. For example, the second conductive pattern 160 may extend from the connection pad 121 of the semiconductor chip 120 along the first surface 120u and the side surface of the semiconductor chip 120 and the upper surface of the substrate 110, to electrically connect the connection pad 121 of the semiconductor chip 120 and the pad 111 of the substrate 110.

As the forming material of the second conductive pattern 160, conductive materials may be used, and for example, it may be formed of a conductive ink that includes metal particles such as aluminum (Al), copper (Cu), gold (Au), platinum (Pt), silver (Ag), and/or nickel (Ni), binder resin, additive (e.g., dispersants, during agents, or the like), solvent, or the like. The solvent of the conductive ink may be removed through a drying process, a curing process, or the like, and may not remain in the second conductive pattern 160. As still another example, as a material of the second conductive pattern 160, metallic materials such as aluminum (Al), copper (Cu), gold (Au), platinum (Pt), silver (Ag), tin (Sn), chromium (Cr), palladium (Pd), or an alloy of two or more these may be used.

In an embodiment,, the second conductive pattern 160 may be formed on the surface of the semiconductor chip 120 and the substrate 110 through a direct printing process. For example, the first conductive pattern 140 may be formed by screen printing, Inkjet printing, aerosol jet printing, or the like.

In an embodiment, the second conductive pattern 160 and the first conductive pattern 140 may be formed through the different processes. For example, the first conductive pattern 140 may be formed by Inkjet printing, which is advantageous for forming fine patterns, and the second conductive pattern 160 may be formed by screen printing, which is advantageous for forming a plurality of patterns. In such an embodiment, the thickness t1 of the first conductive pattern 140 may be thinner than a thickness t2 of the second conductive pattern 160.

In another embodiment, the second conductive pattern 160 and the first conductive pattern 140 may be formed through the same process. For example, the first conductive pattern 140 and the second conductive pattern 160 may be formed by screen printing. In such an embodiment, the thickness t1 of the first conductive pattern 140 may be the same or substantially the same as the thickness t2 of the second conductive pattern 160. In the present disclosure, having substantially the same thickness may include the case of having a fine thickness difference due to a process error. When the first conductive pattern 140 and the second conductive pattern 160 are formed by the same process, the increase of time and cost due to employing of an additional process may be minimized.

A semiconductor package structure is known in which passive components are disposed on the substrate side by side with semiconductor chips, and the semiconductor chips and the passive components are electrically connected through a substrate. In such a semiconductor package structure, the electric characteristics of the passive component may be determined by the wires of the substrate, and depending on the wires existing around the passive component (e.g., between the passive components and the pads of the substrate connected to the semiconductor chip), the connection path between the passive component and the semiconductor chip may be lengthened, thereby deteriorating the electric characteristics of the passive component. In addition, in these package structures, the substrate requires a separate space for mounting passive components.

According to the present disclosure, because the conductive pattern for connection of the passive component is formed on the semiconductor chip to connect the passive component and the semiconductor chip, the electrical path between these may be minimized, and a semiconductor package with excellent electrical characteristics may be provided. In addition, in example embodiments provided herein, a mounting space for the passive component is not required on the substrate (e.g. on the package substrate), and a miniaturized semiconductor package may be advantageously provided.

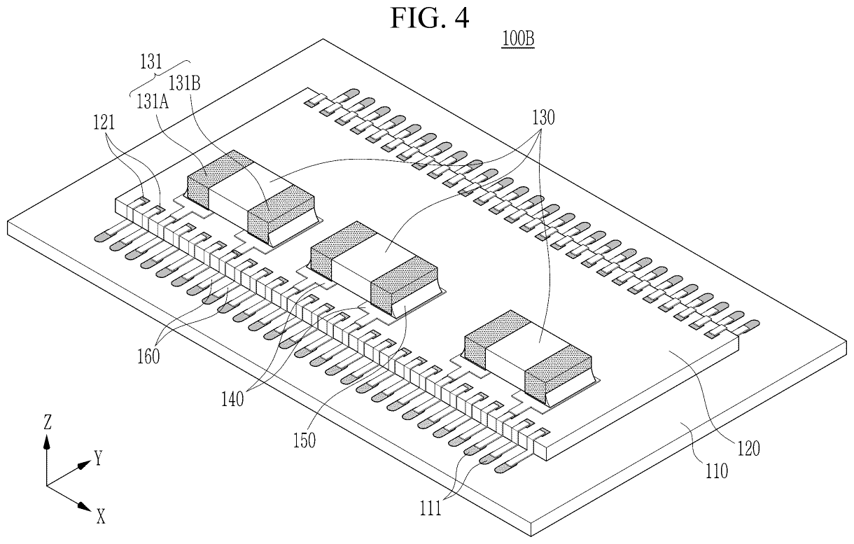

FIG. 4 is a perspective view of a semiconductor package according to another embodiment.

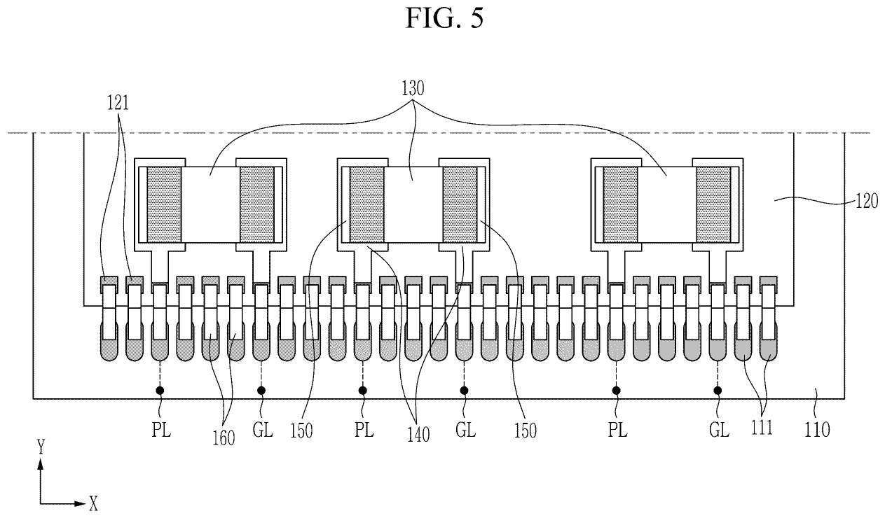

FIG. 5 is a partial plan view of the semiconductor package shown in FIG. 4.

In a semiconductor package 100B, a plurality of passive components 130 may be disposed on the substrate 110.

The plurality of passive components 130 may be arranged adjacent to the plurality of connection pads 121 arranged along the X-direction X.

The first electrode 131A corresponding to a respective passive component 130 of the plurality of passive components 130 may be electrically connected to the power wire PL of the substrate 110, and the second electrode 131B may be electrically connected to the ground wire GL of the substrate 110. Each first electrode 131A corresponding to a respective passive component 130 of the plurality of passive components 130 may be connected to the same power wire PL, and in embodiments, may be connected to power wires PL providing different voltages.

The quantity of the plurality of passive components 130 is not particularly limited, and may be more or less than what is illustrated in the drawings. In addition, the respective types of the plurality of passive components 130 may be the same or different.

For the description of other configurations, unless specifically contradictory, the same contents as described above for the semiconductor package 100A may be applied.

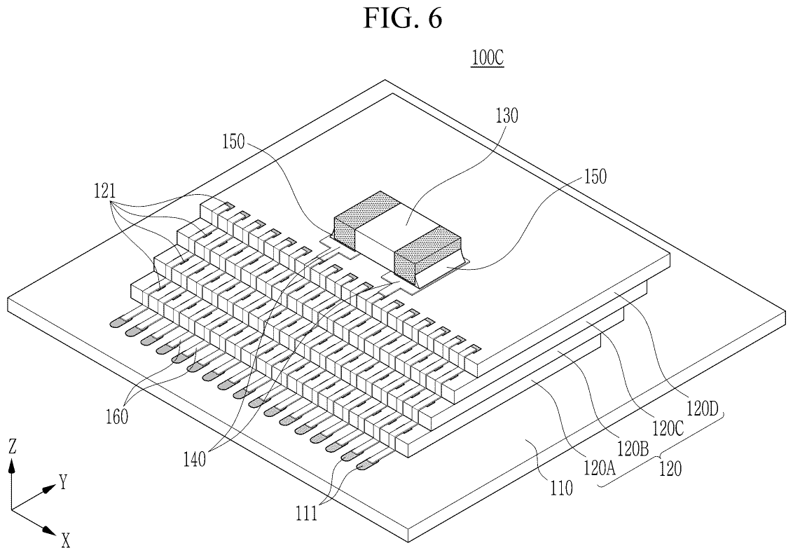

FIG. 6 is a perspective view of a semiconductor package according to still another embodiment.

In a semiconductor package 100C, the stacked plurality of semiconductor chips 120 may be disposed on the substrate 110. For example, the semiconductor chips 120 may include a first semiconductor chip 120A, a second semiconductor chip 120B disposed on the first semiconductor chip 120A, a third semiconductor chip 120C disposed on the second semiconductor chip 120B, and a fourth semiconductor chip 120D disposed on the third semiconductor chip 120C. The plurality of semiconductor chips 120 may be stacked to be offset from one another so that each connection pad 121 of the plurality of connection pads 121 may be exposed. If necessary, an adhesive member for boding between adjacent components may be disposed between respective semiconductor chips from the plurality of semiconductor chips 120, and between the substrate 110 and a semiconductor chip 120 adjacent to the substrate 110.

The passive component 130 may be disposed on one of the plurality of semiconductor chips 120. In an embodiment, the passive component 130 may be disposed on an uppermost fourth semiconductor chip 120D among the plurality of semiconductor chips 120. As the passive component 130 is disposed on an uppermost semiconductor chip 120D, a sufficient mounting area of the passive component 130 may be secured without affecting the wiring space of the semiconductor chips.

The second conductive pattern 160 may extend along a surface of each semiconductor chip of the plurality of semiconductor chips 120 and a surface of the substrate 110, and may electrically connect the substrate 110 and a connection pad 121 of each semiconductor chip of the plurality of semiconductor chips 120. For example, the second conductive pattern 160 may extend along the upper surface of each semiconductor chip of the plurality of semiconductor chips 120 and the side surface of each semiconductor chip, and along the upper surface of the substrate 110, and may electrically connect the substrate 110 and the plurality of connection pads 121 of the semiconductor chips 120.

For the description of other configurations, unless specifically contradictory, the same contents as described above for the semiconductor package 100A may be applied.

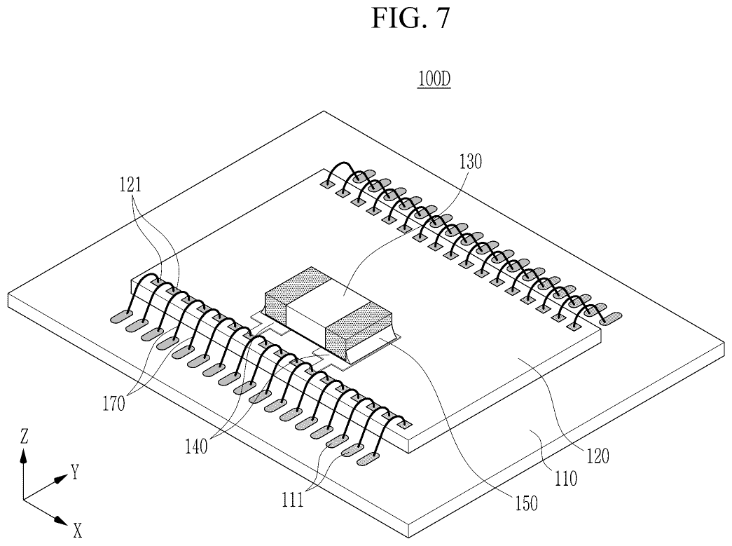

FIG. 7 is a perspective view of a semiconductor package according to still another embodiment.

In a semiconductor package 100D, the connection pad 121 and the substrate 110 may be electrically connected by a conductive wire 170. The conductive wire 170 may have a first end portion bonded to a second end portion bonded to the connection pad 121 of the semiconductor chip 120 and the pad 111 of the substrate 110, and regions other than the first end portion and the second end portion may be spaced apart from the semiconductor chip 120 and the substrate 110. As a material of the conductive wire 170 also, conductive materials may be used, and for example, aluminum (Al), copper (Cu), gold (Au), platinum (Pt), silver (Ag), tin (Sn), chromium (Cr), palladium (Pd), or an alloy of two or more these may be used.

For the description of other configurations, unless specifically contradictory, the same contents as described above for the semiconductor package 100A may be applied.

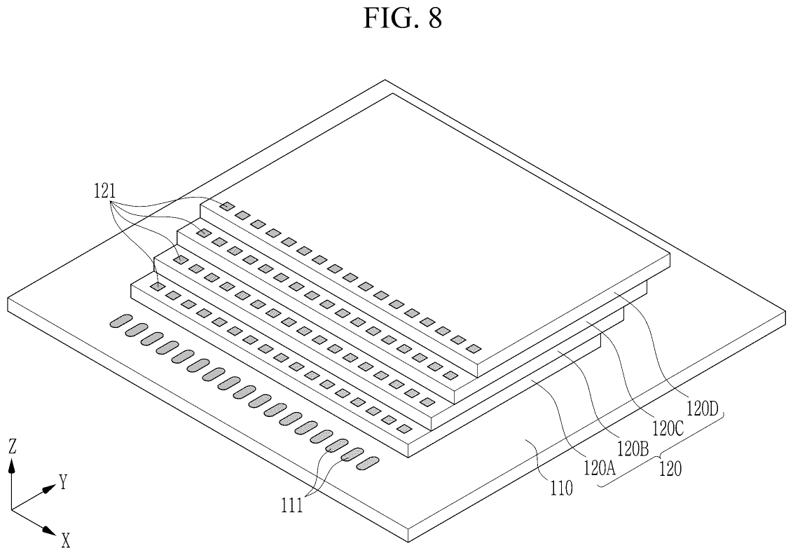

FIG. 8 to FIG. 11 are schematic manufacturing process diagrams of the semiconductor package shown in FIG. 6.

A manufacturing method of a semiconductor package may include disposing the semiconductor chip 120 having the connection pad 121 on the substrate 110, forming the conductive pattern 140 extending from the connection pad 121 of the semiconductor chip 120 to an outer side of the connection pad 121 along the surface of the semiconductor chip 120 and disposing a passive component 130 on the conductive pattern 140.

Hereinafter, the manufacturing method of the semiconductor package 100C shown in FIG. 6 will be described as an example.

First, referring to FIG. 8, the semiconductor chips 120 may be stacked on the substrate 110. For example, on the substrate 110, the first semiconductor chip 120A, the second semiconductor chip 120B, the third semiconductor chip 120C and the fourth semiconductor chip 120D may be sequentially stacked. The plurality of semiconductor chips 120 may be stacked to be offset so that each connection pad of the plurality of connection pads 121 may be exposed. If necessary, an adhesive member (e.g., a die attach film (DAF)) for attachment between adjacent components may be disposed between the plurality of semiconductor chips 120 and between the substrate 110 and the semiconductor chip 120.

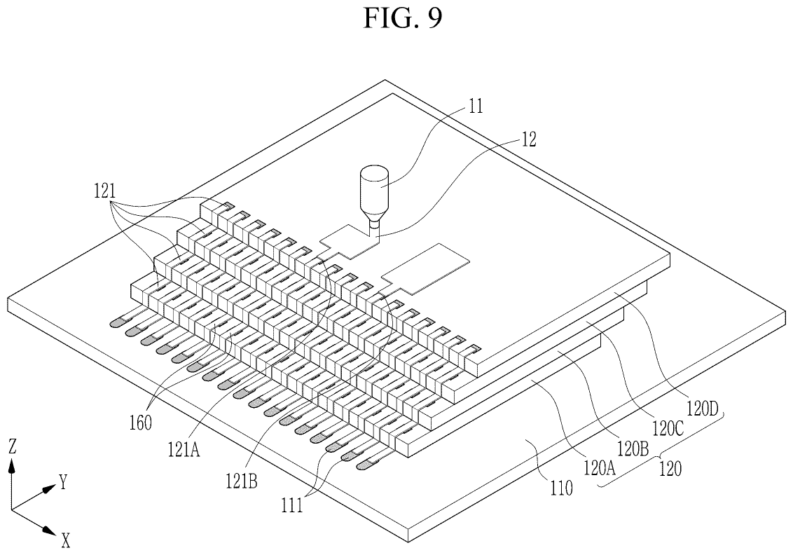

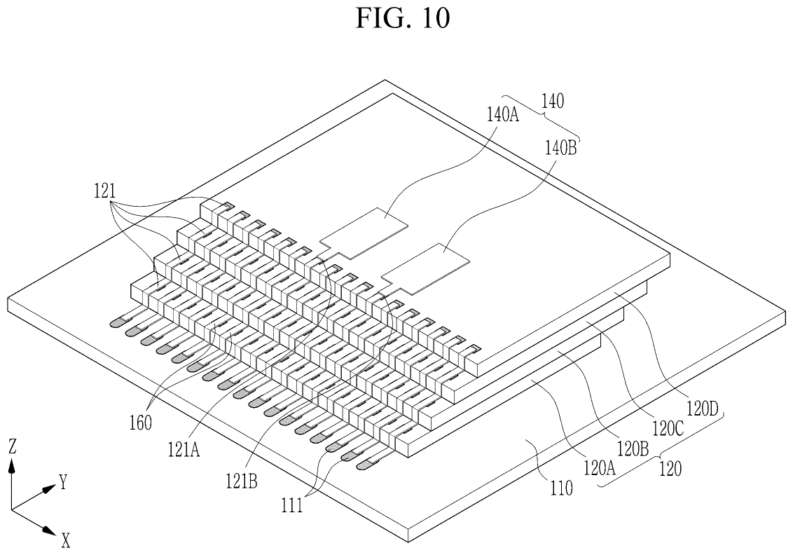

Subsequently, referring to FIG. 9 and FIG. 10, the first conductive pattern 140 and the second conductive pattern 160 may be formed.

The first conductive pattern 140 may be formed to be connected to the connection pad 121, on the surface of the semiconductor chip 120 where the passive component 130 is to be disposed among the semiconductor chips 120. For example, the first conductive pattern 140 may be formed on a surface of the uppermost fourth semiconductor chip 120D where the passive component 130 is disposed, to extend with the connection pad 121 of the fourth semiconductor chip 120D. The 1-1-th conductive pattern 140A connected to the first connection pad 121A and the 1-2-th conductive pattern 140B connected to the second connection pad 121B may be formed on the surface of the fourth semiconductor chip 120D.

The second conductive pattern 160 may extend along the surfaces of the respective semiconductor chips 120 and the surface of the substrate 110, and may be formed to be electrically connected to each of the connection pads 121 of the semiconductor chips 120 and the substrate 110.

Each of the first conductive pattern 140 and as the forming material of the second conductive pattern 160, a conductive ink that includes metal particles such as aluminum (Al), copper (Cu), gold (Au), platinum (Pt), silver (Ag), and/or nickel (Ni), binder resin, additive (e.g., dispersants, during agents, or the like), solvent, or the like may be used. The solvent of the conductive ink may be removed through a drying process, a curing process, or the like, and may not remain in the conductive patterns 140 and 160. As still another example, as a material of each of the first conductive pattern 140 and the second conductive pattern 160, metallic materials such as aluminum (Al), copper (Cu), gold (Au), platinum (Pt), silver (Ag), tin (Sn), chromium (Cr), palladium (Pd), or an alloy of two or more these may be used.

The first conductive pattern 140 and the second conductive pattern 160 may each be formed through a direct printing process. For example, each of the first conductive pattern 140 and the second conductive pattern 160 may be formed by screen printing, Inkjet printing, aerosol jet printing, or the like.

The formation order of the first conductive pattern 140 and the second conductive pattern 160 is not particularly limited.

In an embodiment, the second conductive pattern 160 and the first conductive pattern 140 may be formed through the different processes. For example, the first conductive pattern 140 may be formed by Inkjet printing, which is advantageous for forming fine patterns (a method of spraying a conductive ink 12 on an object by using a nozzle 11; refer to FIG. 9), and the second conductive pattern 160 may be formed by screen printing, which is advantageous for forming a plurality of patterns. In such an embodiment, thickness of the first conductive pattern 140 may be thinner than a thickness of the second conductive pattern 160.

In another embodiment, the second conductive pattern 160 and the first conductive pattern 140 may be formed through the same process. For example, the first conductive pattern 140 and the second conductive pattern 160 may be formed by screen printing. In such an embodiment, the thickness t1 of the first conductive pattern 140 and the thickness t2 of the second conductive pattern 160 may be the same or substantially the same. In the present disclosure, having substantially the same thickness may include having a fine thickness difference due to a process error. When the first conductive pattern 140 and the second conductive pattern 160 are formed by the same process, the increase of time and cost due to employing of an additional process may be minimized.

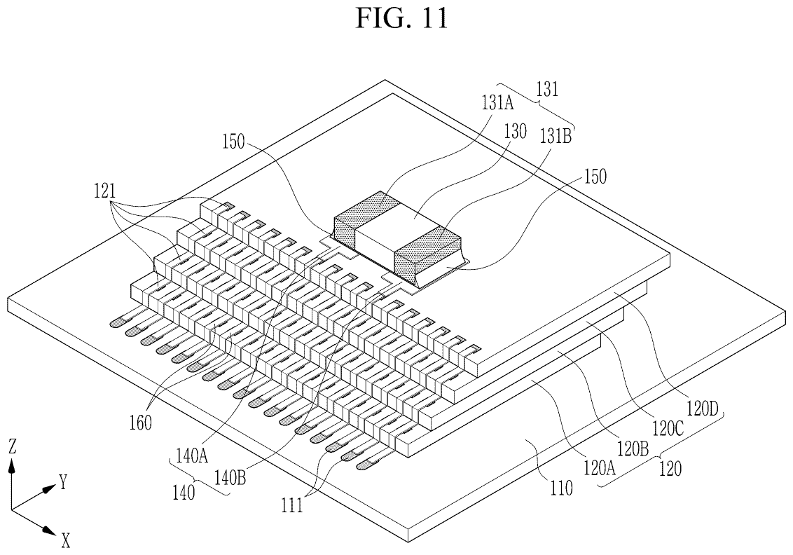

Subsequently, referring to FIG. 11, the passive component 130 may be disposed on the first conductive pattern 140. The passive component 130 may be disposed so that the first electrode 131A, the 1-1-th conductive pattern 140A, and the second electrode 131B may be located on the 1-2-th conductive pattern 140B.

The passive component 130 may be mounted on the first conductive pattern 140 through the conductive member 150. The conductive member 150 may be formed of a solder paste, and may be formed by applying the solder paste to the electrode 131 of the passive component 130, disposing the passive component 130 on the first conductive pattern 140 and then melting and cooling the solder paste by the solder reflow process.

While this disclosure has been described in connection with what is presently considered to be practical embodiments, it is to be understood that the invention is not limited to the disclosed embodiments, but is intended to cover various modifications and equivalent arrangements included within the spirit and scope of the appended claims.

Additionally, the embodiments of the present disclosure are not independent from each other and may be implemented in combination with each other unless there is a particular conflict. Accordingly, embodiments in which embodiments of the present disclosure are combined should also be considered to be included in the present disclosure.

What is claimed is:

1. A semiconductor package, comprising:
a substrate;
a semiconductor chip disposed on the substrate, electrically connected to the substrate, and having a connection pad at a surface of the semiconductor chip;
a passive component disposed on the semiconductor chip; and
a first conductive pattern extending from the connection pad to an outer side of the connection pad, along the surface of the semiconductor chip, and electrically connecting the semiconductor chip and the passive component, at least a portion of which is disposed between the semiconductor chip and the passive component.

2. The semiconductor package of claim 1, wherein the first conductive pattern covers at least a portion of the connection pad.

3. The semiconductor package of claim 1, wherein:
the passive component and the connection pad are disposed on a first surface of the semiconductor chip; and
the first conductive pattern extends along the first surface of the semiconductor chip.

4. The semiconductor package of claim 1, wherein the passive component does not overlap with the connection pad.

5. The semiconductor package of claim 1, further comprising a conductive member disposed between the first conductive pattern and the passive component and electrically connecting the first conductive pattern and the passive component.

6. The semiconductor package of claim 1, further comprising a second conductive pattern extending along the surface of the semiconductor chip and a surface of the substrate, and electrically connecting the connection pad and the substrate.

7. The semiconductor package of claim 6, wherein a first thickness of the first conductive pattern and a second thickness of the second conductive pattern are the same.

8. The semiconductor package of claim 6, wherein a first thickness of the first conductive pattern is smaller than a second thickness of the second conductive pattern.

9. The semiconductor package of claim 1, further comprising a conductive wire electrically connecting the connection pad and the substrate.

10. A semiconductor package, comprising:
a substrate;
a semiconductor chip disposed on the substrate, electrically connected to the substrate, and having a plurality of connection pads comprising a first connection pad and second connection pad at a surface of the semiconductor chip;
a passive component disposed on the semiconductor chip, and having a first electrode and a second electrode;
a first conductive pattern extending from the first connection pad to an outer side of the first connection pad along the surface of the semiconductor chip, wherein the first conductive pattern comprises a first pad region, at least a portion of which is disposed between the semiconductor chip and the first electrode, and a first connection region connecting the first pad region and the first connection pad, and electrically connecting the first connection pad and the first electrode; and
a second conductive pattern extending from the second connection pad to an outer side of the second connection pad, along the surface of the semiconductor chip, wherein the second conductive pattern comprises a second pad region, at least a portion of which is disposed between the semiconductor chip and the second electrode, and a second connection region connecting the second pad region and the second connection pad, and electrically connecting the second connection pad and the second electrode.

11. The semiconductor package of claim 10, wherein:
the plurality of connection pads is arranged along a first direction; and
the passive component is spaced apart from the plurality of connection pads in a second direction intersecting the first direction.

12. The semiconductor package of claim 11, wherein a first width of each of the first connection region and the second connection region in the first direction is smaller than a second width of each of the first pad region and the second pad region in the first direction.

13. The semiconductor package of claim 11, wherein a first length of each of the first connection region and the second connection region in the second direction is smaller than a second length of each of the first pad region and the second pad region in the second direction.

14. The semiconductor package of claim 11, wherein the first electrode and the second electrode are spaced apart from each other in the first direction.

15. The semiconductor package of claim 10, wherein:
the first pad region and the first connection region are integrated with each other; and
the second pad region and the second connection region are integrated with each other.

16. The semiconductor package of claim 10, wherein:
the first connection pad and the first electrode are electrically connected to a power wire of the substrate; and
the second connection pad and the second electrode are electrically connected to a ground wire of the substrate.

17. The semiconductor package of claim 10, wherein the passive component comprises a multilayer ceramic capacitor.

18. A semiconductor package, comprising:
a substrate;
a plurality of semiconductor chips disposed on the substrate, electrically connected to the substrate, and having a plurality of connection pads at a surface of each corresponding semiconductor chip of the plurality of semiconductor chips, wherein each semiconductor chip of the plurality of semiconductor chips is stacked to be offset such that each connection pad of the plurality of connection pads at the surface of the corresponding semiconductor chip is exposed;
a passive component disposed on a first semiconductor chip of the plurality of semiconductor chips; and
a first conductive pattern extending from the connection pad of the first semiconductor chip to an outer side of the connection pad along a surface of the first semiconductor chip, and electrically connecting the first semiconductor chip and the passive component, at least a portion of which is disposed between the first semiconductor chip and the passive component.

19. The semiconductor package of claim 18, wherein the first semiconductor chip is an uppermost semiconductor chip with respect to the substrate, among the plurality of semiconductor chips.

20. The semiconductor package of claim 18, further comprising a second conductive pattern extending along the surface of each semiconductor chip of the plurality of semiconductor chips and a surface of the substrate, and electrically connecting the substrate and a corresponding connection pad of each semiconductor chip of the plurality of semiconductor chips.
